(19) United States
(12) Patent Application Publication
(10) Pub. No.: US 2017/0122983 A1
(43) Pub. Date: May 4, 2017

(54) TESTING HEAD COMPRISING VERTICAL PROBES

(71) Applicant: Technoprobe S.p.A., Cernusco Lombardone (IT)

(72) Inventors: Daniele Acconcia, Cernusco Lombardone (IT); Raffaele Ubaldo Vallauri, Cernusco Lombardone (IT)

(21) Appl. No.: 15/405,062

(22) Filed: Jan. 12, 2017

Related U.S. Application Data
(63) Continuation-in-part of application No. PCT/EP2015/078057, filed on Nov. 30, 2015.

(30) Foreign Application Priority Data
Dec. 4, 2014 (IT) MI2014A002089

(51) Int. Cl. G01R 1/073; G01R 1/067

(52) U.S. Cl. CPC G01R 1/07357; G01R 1/06716

(57) ABSTRACT

A testing head comprising vertical probes includes at least one guide provided with guide holes for housing a plurality of contact probes, each of the contact probes having at least one contact tip able to ensure the mechanical and electrical contact with a corresponding contact pad of a device under test, the guide being housed in a containment element of the testing head. Suitably, each of the contact probes comprises a deformed portion, placed in a bending zone between the guide and the device under test, that deformed portion being adapted to further deform during the normal working of the testing head and being prolonged, at least towards the device under test, by an end portion having a diameter suitable to realize the contact tip, the end portion having a longitudinal extension or height exceeding 500 μm.

### BACKGROUND

1. Technical Field

The present disclosure refers to a testing head comprising vertical probes.

The disclosure refers particularly but not exclusively to a testing head comprising non-blocked vertical probes to test electronic devices integrated on semiconductor wafer and the following description is made referring to this application field with the only purpose of simplifying the exposition.

2. Description of the Related Art

As it is well known, a testing head is basically a device adapted to place a plurality of contact pads of a microstructure into electrical contact with corresponding channels of a testing machine executing the test thereof.

The test performed on integrated circuits allows to detect and isolate defective circuits yet in the production phase. Normally, the testing heads are thus used for electrically testing the circuits integrated on wafer before cutting and assembling them inside a chip-containing package.

A testing head comprising vertical probes usually includes at least one pair of parallel plates or guides arranged at a certain distance from each other in order to leave a free area or air gap therebetween, as well as a plurality of specific mobile contact elements. The pair of guides particularly includes an upper guide and a lower guide, which both are provided with guide holes inside which the mobile contact elements slide axially, which elements are normally made of special alloys wires having good electrical and mechanical proprieties. In the following description, they will be referred to as the contact probes of the testing head.

The good connection between the contact probes and the contact pads of the device under test is guaranteed by pressing the testing head on the device itself, the mobile contact probes bending inside the air gap between the two guides during that pressing contact. Testing heads of this kind are usually called “vertical probe head” or testing heads comprising vertical probes.

Substantially, the known testing heads comprising vertical probes have an air gap where a bending of the contact probes occurs, that bending being helped by a suitable configuration of the probes themselves or of the their guides, as schematically shown in FIG. 1A.

In that FIG. 1A, a testing head 1 includes at least one upper guide 2 and one lower guide 3, having respective upper 4 and lower 5 guide holes inside which at least one contact probe 6 slides.

The contact probe 6 has at least one end or contact tip 7. The terms end or tip here and in the following specify an end portion, not necessarily being sharp. In particular, the contact tip 7 abuts on a contact pad 8 of a device under test 9, realizing the electrical and mechanical contact between that device and a testing apparatus (not shown), that testing head forming a terminal element thereof.

The upper 2 and lower 3 guides are suitably separated by an air gap ZA allowing the deformation of the contact probes 6. Moreover, the upper 4 and lower 5 guide holes are sized so as to house with tolerance and guide each contact probe 6.

In some cases, the contact probes 6 are fixedly fastened to the head itself at the upper guide 2: in such a case, the testing heads are referred to as testing heads comprising blocked probes.

However, more frequently testing heads are used having probes not fixedly fastened, but being interfaced to a so-called board by means of an element able to perform a spatial transformation of the contact zones and for that reason called “space transformer”: thus in that case the testing heads are referred to as testing heads comprising non-blocked probes.

In this case, the contact probes 6 have another contact tip 7A towards a plurality of contact pads 8A of the space transformer 10, the good electrical contact between the contact probes 6 and the space transformer 10 being guaranteed similarly to the contact with the device under test 9 by pressing the contact probes 6 against the contact pads 8A of the space transformer 10.

The main advantage of a testing head comprising non-blocked probes is the possibility to replace the probe assembly, or one or more defective probes inside a probe block in an easier way with respect to the testing heads comprising blocked probes.

However, in this case, the upper 2 and lower 3 guides must have suitable expedients in order to guarantee the proper positioning of the contact probes 6 also without a device under test 9 abutted on their contact tips 8, or in case of probe block movement during possible replacements or also in case of cleaning operations.

Such contact probes 6 usually have a pre-deformed configuration also without the contact of the testing head 1 with the device under test 9. In particular, it is also possible to obtain such an initial pre-deformation simply by means of a misalignment of the upper 2 and lower 3 guides. The initial pre-deformation acts as a “piloting” for the proper bending of the probe 6 during the operation of the corresponding testing head 1, namely during the contact of the probes 6 with the device under test 9.

The shape of the deformation to which the probes are undergone and the force needed to cause that deformation are dependent on many factors, such as for example:
the physical characteristics of the alloy constituting the probes;
the offset value between the guide holes in the upper guide and the corresponding guide holes in the lower guide and their distance.

Therefore, all these characteristics are to be evaluated and calibrated in the manufacturing phase of a testing head, and the proper electrical connection between probes and device under test has to be always guaranteed.

Substantially, the proper operation of a testing head is related to the vertical movement, called overtravel, of the probes contained therein and to the horizontal movement, called scrub, of the contact tips of those probes on the corresponding contact pads.

In the case of known testing heads, there are intrinsic limits of those parameters. In fact, the maximum vertical movement of a probe is equal to the dimensions of the probe part protruding with respect to the lower guide, that protruding part entering the lower guide in case of contact of the testing head with the device under test, due to the bending and deformation of the probe itself.

However, the height of that protruding part is limited by the probe fragility and it is normally between 300 and 500 μm.

Actually, that vertical movement value of the probes is reachable only theoretically, since already under much smaller movements, problems arise, which problems are related to the probes getting stuck in the guide holes, particularly in the lower guide holes, and to the permanent deformation of the probes.

It is known to overcome this problem by using probes having a real deformation DD inside the air gap, as schematically shown in FIG. 1B. Those probes guarantee an almost total exploitation in terms of vertical movement of the probe part protruding from the lower guide, but they have a considerable realization as well as maintenance complexity.

Moreover, the lower guide presence considerably limits the possibility of horizontal movement of the probe tip; in fact that movement strictly depends on the difference between the hole diameter and the probe diameter.

In order to overcome this drawback, a testing head comprising a plurality of probes provided with a pre-deformed section placed between the testing head and the device under test has been devised by the Applicant, as described for example in the U.S. Patent Publication No. 2002/0070743.

In particular, each contact probe of that testing head has a pre-deformed section, having any symmetrical and asymmetrical shape, placed in a zone indicated as bending zone arranged between a guide and the device under test and adapted to further deform during the normal operation of the testing head, the bending zone thus being actually external to the testing head itself.

In that way, it is in fact possible to increase the vertical movement value to which the contact probe can be subjected.

A probe friction zone is also provided with a corresponding guide hole, such as to prevent the probe from coming out too easily if a device under test is not present.

However, although that known solution is advantageous from different points of view, it has important drawbacks, the first being the imperfect alignment of the probe contact tips of the testing head with respect to the contact pads of a device under test, exactly due to the presence of the pre-deformed section; particularly, that imperfect alignment causes a shortening of the working life of the probes and thus of the testing head.

Furthermore, the realization of the pre-deformed section of the contact probes requires using complicated photolithographic techniques, with a consequent rise in the manufacturing costs of the contact probes and thus of the overall testing head.

### BRIEF SUMMARY

The testing head to test semiconductor integrated devices is able to guarantee a proper electrical contact of the contact probes with a device under test and at the same time to guarantee a long working life to the testing head containing them, so overcoming the problems tied to the prior art solutions.

According to an aspect of the disclosure the testing head includes a plurality of probes provided with a deformed portion placed between the testing head and the device under test, the deformed portion being prolonged at least towards the device under test with by end portion having a diameter suitable to realize a contact tip and having such a length to allow enhancing the working life of the testing head by bearing a great number of contacts, both on pads of a device under test and on cleaning abrasive cloths, actually realizing a “consumption” contact tip.

The testing head comprising vertical probes includes at least one guide provided with guide holes for housing a plurality of contact probes, each of the contact probes having at least one contact tip able to ensure the mechanical and electrical contact with a corresponding contact pad of a device under test, the guide being housed in a containment element of the testing head, characterized in that each of the contact probes comprises a deformed portion, placed in a bending zone between the guide and the device under test, that deformed portion being adapted to further deform during the normal working of the testing head and being prolonged, at least towards the device under test, by an end portion having a diameter suitable to realize the contact tip and having a longitudinal extension or height exceeding 500 μm.

Moreover, according to another aspect of the disclosure, the deformed portion can have a section having at least one dimension lower than a corresponding dimension of the contact probe.

The deformed portion particularly can have a section having at least one dimension equal to 20%-70%, preferably 50%, of the corresponding contact probe dimension.

According to yet another aspect of the disclosure, the testing head comprising vertical probes can further include at least one elastic sheet, retained within the testing head and provided with respective openings for the passage of the contact probes.

In particular, the deformed portion of the contact probes can be arranged between the guide and the elastic sheet and the end portion can be disposed between the elastic sheet and the device under test.

Furthermore, the openings can be positioned in correspondence of the deformed portion of the contact probes.

According to another aspect of the disclosure, the testing head comprising vertical probes can further include a frame associated with the containment element and arranged to retain the elastic sheet.

Particularly, the elastic sheet can be connected to the frame by means of suitable connection means.

Furthermore, the elastic sheet can be made of Kapton®.

According to yet another aspect of the disclosure, the elastic sheet can be housed in a recess of the frame and can be removably fastened to it by means of connection means in the form of glue dots or screws.

Particularly, the elastic sheet can have such dimensions to cover the containment element and the frame and it can be enclosed and kept by them, possibly by means of connection means in the form of glue dots or screws.

According to another aspect of the disclosure, the deformed portion can be substantially C-shaped.

In particular, that deformed portion can be configured so as to realize a contact tip and a contact head of the contact probe aligned with each other according to a longitudinal axis of the contact probe perpendicular to a plane of the device under test.

Alternatively, the deformed portion can be configured so as to realize a contact tip and a contact head of the contact probe axially offset from each other with respect to a longitudinal axis of the contact probe perpendicular to a plane of the device under test.

According to yet another aspect of the disclosure, the end portion can be provided with a thinned portion of suitable diameter to provide the contact tip, the remaining part of the end portion and the contact probe having larger dimensions.

Particularly, the thinned portion can have a substantially constant section.

Alternatively, the thinned portion can have a tapered shape having a decreasing section towards the contact pad of the device under test.

Moreover, the end portion can be centered and aligned with respect to a longitudinal axis of the contact probe perpendicular to a plane of the device under test.

Alternatively, the end portion can be eccentric and axially offset with respect to a longitudinal axis of the contact probe perpendicular to a plane of the device under test.

According to a further aspect of the disclosure, the contact probes can have a non-circular cross section and the guide holes can have a corresponding non-circular cross section.

According to yet another aspect of the disclosure, each of the contact probes can comprise a further deformed section suitable to provide a friction zone with a corresponding guide hole in the guide.

In particular, the guide can comprise a plurality of superimposed layers, each provided with respective guide holes for the housing of the contact probes.

Those guide holes of the layers of the guide can be suitably offset with respect to an axis perpendicular to the layers, causing a deformation of a portion of the contact probe and realizing a friction zone.

According to yet another aspect of the disclosure, each of the contact probes can comprise at least one configuration shaped as a needle eye, equipped with a flexible peripheral portion formed around a suitable hole which realizes a friction zone between a contact probe and a corresponding guide hole.

Finally, that configuration shaped as a needle eye can comprise at least one first and one second hole realized inside the flexible peripheral portion.

The characteristics and advantages of the testing head according to the disclosure will be evident from the following description of an embodiment thereof, made by way of an indicative non-limiting example with reference to the annexed drawings.

### BRIEF DESCRIPTION OF THE SEVERAL VIEWS OF THE DRAWINGS

FIGS. 1A and 1B schematically show embodiments of a testing head according to the prior art;

FIG. 2 schematically shows a testing head according to an embodiment of the disclosure;

FIGS. 3A-3C and 4A-4F schematically show enlarged cross sections of the testing head of FIG. 2;

FIG. 5 schematically shows an alternative embodiment of the testing head of FIG. 2;

FIGS. 6A-6C schematically show enlarged views of alternative embodiments of a detail of the testing head of FIG. 5;

FIGS. 7, 8A-8C schematically show further alternative embodiments of the testing head of FIG. 2; and

FIGS. 9A and 9B schematically show enlarged views of alternative embodiments of a further detail of the testing heads of FIGS. 2, 5, 7 and 8.

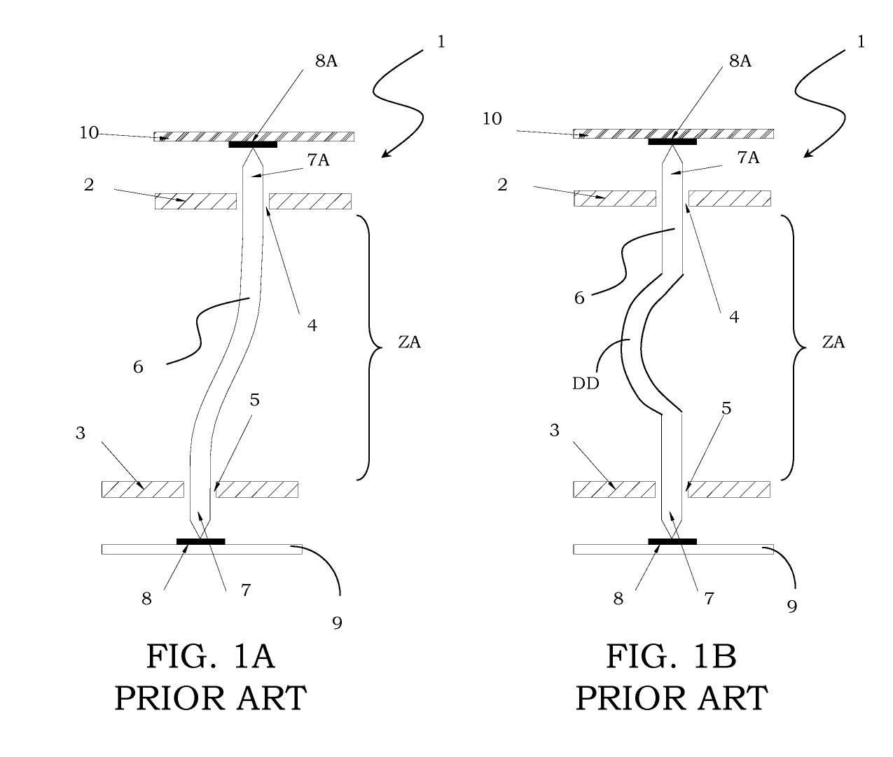

### DETAILED DESCRIPTION

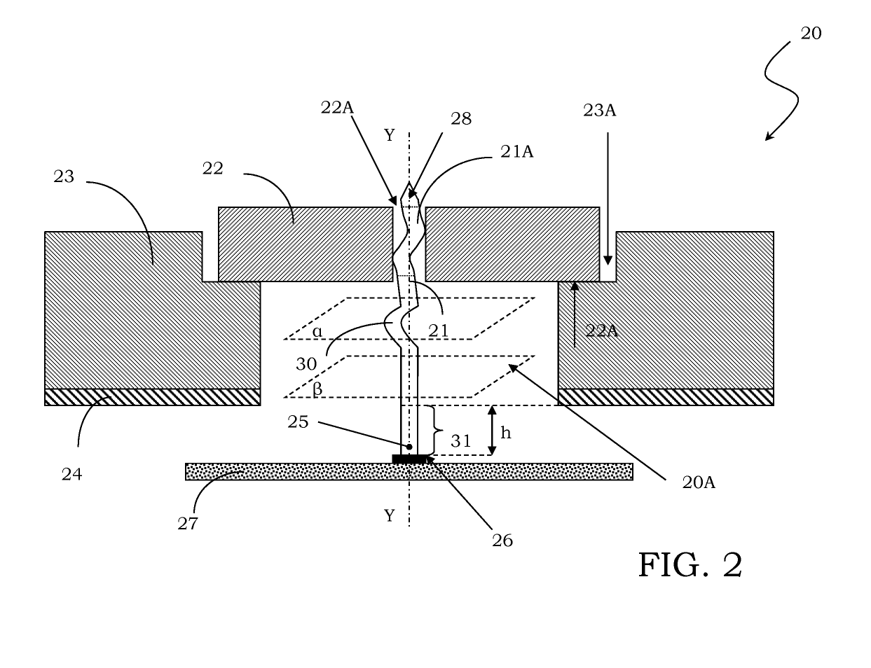

With reference to those figures, and particularly to FIG. 2, a testing head according to an embodiment of the disclosure is schematically shown and globally indicated with 20.

It should be noted that the figures represent schematic views of the testing head according to embodiments of the disclosure and are not drawn to scale, on the contrary they are drawn such as to highlight the important characteristics of the embodiments. Moreover, in the figures, the different parts are shown in a schematic way, their shape being able to change according to the desired application. Finally, specific expedients described as related to an embodiment shown in one figure can be used also for the other embodiments shown in the other figures.

The testing head 20 comprises vertical probes and in particular comprises a plurality of contact probes apt to contact a device under test.

In the simplified example of FIG. 2, the testing head 20 comprises a single contact probe 21 for sake of simplicity. The contact probe 21 is housed in a guide hole 22A of a guide 22, in turn being housed in a suitable recess 23A of a containment element 23 or housing of the testing head 20. Such containment element 23 can be of a ceramic type or can be made of a material being commonly used in the printed circuit boards (PCB) manufacturing or of any material being used in the testing heads field. More particularly, the guide 22 is abutting, at a portion 22A of its undercut wall, on the recess 23A of the containment element 23.

The contact probe 21 has an end or contact tip 25 adapted to abut on a corresponding contact pad 26 of a device under test 27. As above, here and in the following with the terms end or tip it is meant an end portion, not necessarily being sharp.

In the shown example, the testing head 20 comprises non-blocked probes and has a further end or contact tip 28, usually called contact head, adapted to abut on a corresponding contact pad of a space transformer (not shown).

Advantageously according to an embodiment of the disclosure, the contact probe 21 has a deformed portion 30, placed in a bending zone 20A between the guide 22 and the device under test 27, such deformed portion 30 being adapted to further deform during the normal working of the testing head 20 and being prolonged, at least toward the device under test 27, by an end portion 31 having a diameter suitable to realize the contact tip 25.

Particularly, the end portion 31 has a length being calibrated to guarantee that the contact probe 21 bears a great number of contacts, both on pads of a device under test and on cleaning abrasive cloths. In that way, the end portion 31 allows realizing a contact probe 21 having a substantially “consumption” contact tip, as it will be explained in the following description.

In particular, the deformed portion 30 can have any symmetrical and asymmetrical shape. In a preferred embodiment shown in FIG. 2, that deformed portion 30 is substantially C-shaped.

In particular, in the example of FIG. 2, the end portion 31 is realized by a rod-shaped portion, ending in the contact tip 25 and having dimensions comparable with the rest of the contact probe 21. Therefore, the contact tip 25 ends with a contact zone, which is not necessarily point-shaped, being adapted to abut on a corresponding contact pad 26 of a device under test 27.

It should be underlined that the deformed portion 30 can also be configured in such a way to realize, at the end of the end portion 31, a contact tip 25 that is not aligned, according to an axis YY perpendicular to the plane of the device under test 27, with respect to the contact head 28, not shown in the figures.

According to this embodiment, the section of the contact probe 21, which will be called probe section, equivalent to the section of the end portion 31, has dimensions suitable to realize the contact zone of the contact tip 25, which will be called tip section.

In other words, the probe section, corresponding to the section of its end portion 31, is substantially equal to the tip section.

By defining as section diameter a maximum transversal dimension thereof, it is possible to consider probe and tip sections having a diameter varying from 5 μm to 80 μm.

The substantially rod-shaped end portion 31 is particularly realized so as to have a longitudinal extension or height h between 200 μm and 650 μm, for a contact probe 21 having an overall length varying from 1 mm to 10 mm, meaning with h the height of the probe portion protruding from the testing head body, up to its contact tip 25, substantially up to the contact pad 26 of the device under test 27. Therefore, that height h substantially corresponds to the height of the end portion 31, as defined above. In a preferred example, this end portion 31 has a height h greater than 500 μm, so as to allow a greater consumption of that end portion 31 with respect to the probes realized according to the prior art, without affecting their behavior.

In that way, the contact probe 21 can undergo a number of cleaning operations of the contact tips 25, for example by means of abrasive cloths, which is certainly higher compared to the known probes, keeping a constant section for its contact zone for a long time, moving up along the end portion 31, thus guaranteeing constant performances for the probe itself for a long working life time and a substantially “consumption” contact tip.

It should be underlined that precisely the combination of the presence of the deformed portion 30 and the end portion 31 having a greater length than the known probes allows an easier and more uniform control of the contact of the contact probes 21 on the respective contact pads 26 of the device under test 27 preventing an excessive and non-uniform probe consumption and allowing a reshape of their “consumption” contact tip, thus enhancing the working life of the overall head.

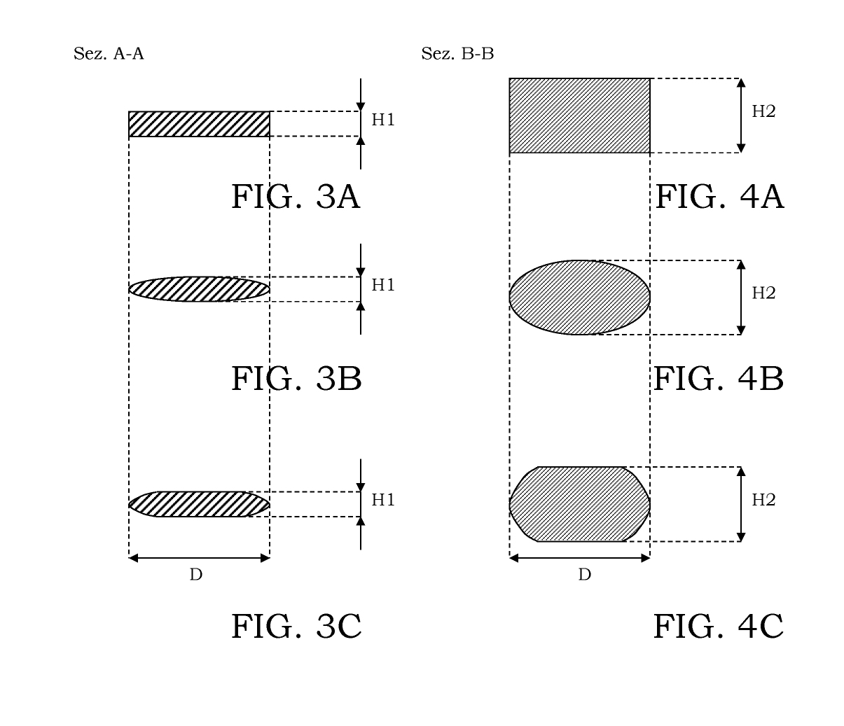

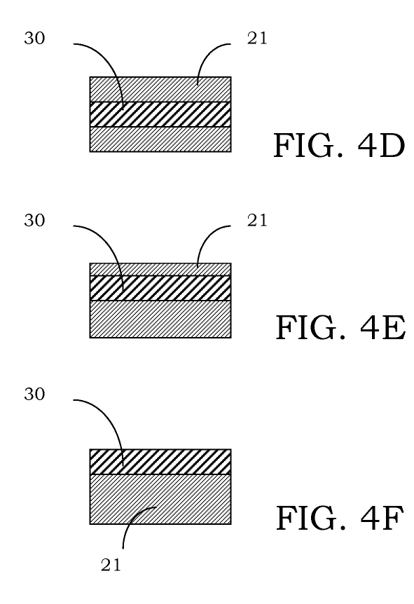

According to an alternative embodiment, the deformed portion 30 of the contact probe 21 also has dimensions being reduced according to at least one progress direction of its section, as shown in the FIGS. 3A-3C and 4A-4C.

More particularly, FIGS. 3A-3C show a section A-A of the contact probe 21 taken at a plane α perpendicular to a longitudinal axis Y-Y of the contact probe 21 itself, as shown in FIG. 2, that longitudinal axis Y-Y being perpendicular to the device under test 27 during the working of the testing head 20, namely being vertically arranged in the reference of FIG. 2. That plane α is arranged at the deformed portion 30.

Similarly, FIGS. 4A-4C show a section B-B of the contact probe 21 taken at a plane β, again perpendicular to the longitudinal axis Y-Y of the contact probe 21 itself, as shown in FIG. 2, but being arranged at a different probe section from the deformed portion 30.

More particularly, those figures refer to probes having cross sections with different shapes, particularly non-circular cross sections, in the shown examples having a rectangular cross section (FIGS. 3A and 4A), an elliptic cross section (FIGS. 3B and 4B) or a mixed curvilinear profile cross section (FIGS. 3C and 4C).

According to the embodiment shown in those figures, the cross section A-A at the deformed portion 30 can have at least one dimension H1, particularly the height, having a value lower than a corresponding dimension H2 of the cross section B-B of the remaining part of the contact probe 21. More particularly, that dimension H1 of the section at the deformed portion 30 can be equal to 30%-100% of the corresponding dimension H2 of the remaining part of the contact probe 21.

In the examples of FIGS. 3A-3C and 4A-4C, the cross sections at the deformed portion 30 and at the remaining part of the contact probe 21 have a further equal dimension D. Of course, the further dimension D, in particular the diameter, at the deformed portion 30 can also have a different value, in particular less than a corresponding dimension of the remaining part of the contact probe 21 and in particular equal to 20%-70%, preferably 50%, of that corresponding dimension of the remaining part of the contact probe 21.

The deformed portion 30 can be realized by means of a material removal from the body of the contact probe 21. As schematically shown in FIG. 4D, which shows section and top views of the contact probe 21, such a material removal can be symmetrical with respect to a longitudinal symmetry plane of the contact probe 21 (in particular a plane parallel to the plane of FIG. 2) obtaining a deformed portion 30 having the same symmetry plane. Alternatively, that removal can be asymmetric, for example at only one of the faces of the contact probe 21, obtaining a deformed portion 30 axially offset with respect to the remaining part of the body of the contact probe 21, as schematically shown in FIG. 4E. Further, such a removal may affect only one side of the body of the contact probe 21, as schematically shown in FIG. 4F.

In its more general form, the contact probe 21 thus includes a deformed portion 30 being thinner than the remaining part of the contact probe 21, namely with at least one dimension being reduced with respect to a corresponding dimension of the remaining part of the contact probe 21.

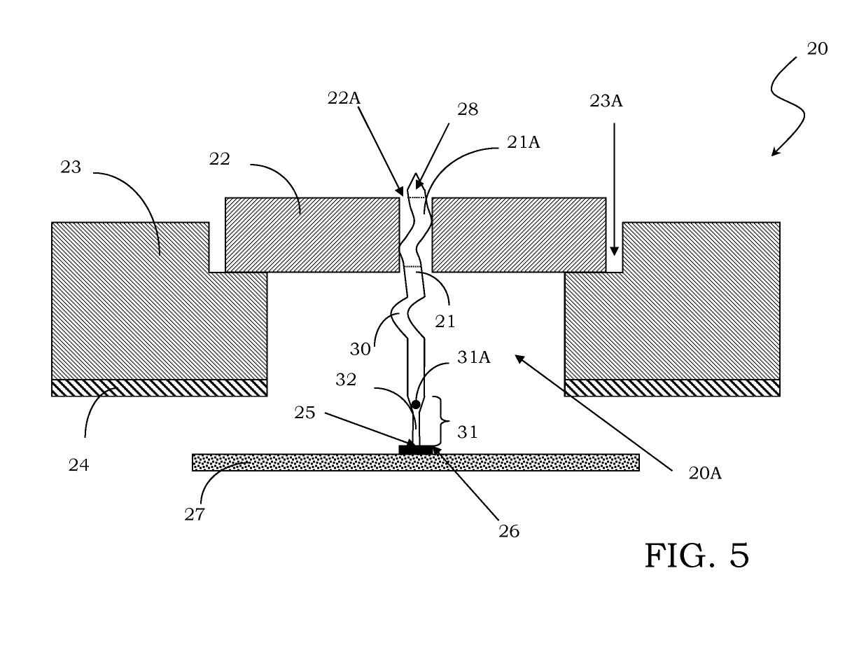

According to an alternative embodiment shown in FIG. 5 by way of a mere illustrative example, the contact probe 21 includes an end portion 31 provided with a thinned portion 32 of suitable diameter to provide the contact tip 25, the remaining part of the end portion 31 and of the contact probe 21 instead having larger dimensions, in particular a larger diameter.

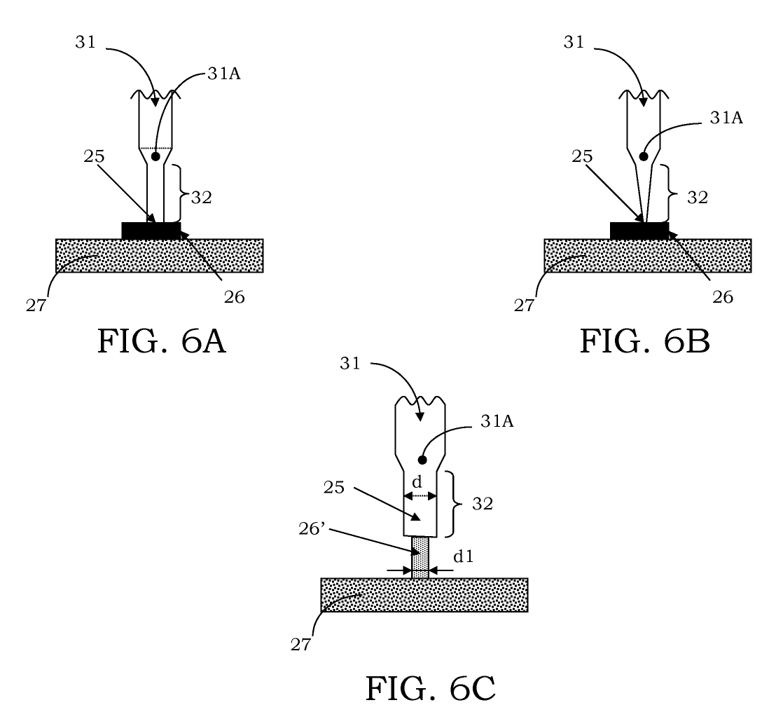

More particularly, the end portion 31 includes a section 31A substantially having a conical frustum shape, with base area corresponding to the probe section and top area having an extension less than that probe section and particularly being equal to the tip section corresponding to the contact zone of the contact tip 25; similarly, the section of the thinned portion 32 will be equal to the tip section, in turn having a substantially cylindrical shape, as shown in more detail in FIG. 6A.

In that case, the area of the tip section is selected to be equal to 20-80%, preferably equal to 50%, of the probe section area.

Alternatively, the thinned portion 32 can be a further tapered portion having a decreasing section towards the contact pad 26 of the device under test 27, ending in a contact tip 25 being really point-shaped, as shown in FIG. 6B.

The thinned portion 32 can also be a rod-shaped portion with a flat tip, having dimensions larger than the solution shown in FIG. 6A, as schematically shown in FIG. 6C. Such alternative embodiment can be particularly used in case of contacts in the form of small copper pillars 33, the so-called Cu pillars. In that case, the cross extension or diameter d of the thinned portion 32 is selected in order to be larger than the cross extension or diameter d1 of the small copper pillar 33.

However, the presence of a contact tip 25 having a non-pointed end portion allows minimizing the alignment problems in case of contacts different from the contact pads, such as for example in the above-mentioned case of the small copper pillars or Cu Pillars, but also in case of contact bumps, the contact with the contact probe 21 occurring on a surface and not only in a point or in case in a line, as in the case of the skates or blades used in the prior art.

The thinned portion 32 can be centrally arranged, that is substantially along the longitudinal axis Y-Y of the contact probe 21, as shown in the figures. Alternatively, that thinned portion 32 can be positioned in an axially offset way with respect to such a longitudinal axis Y-Y, for example, it can be substantially aligned with respect to a lateral wall of the contact probe 21.

It is also possible to consider a thinned portion 32 including a tapered portion being prolonged by a further portion having a substantially constant section and having dimensions suitable to act as a contact tip 25. Further shapes of the end portion 31 and of the thinned portion 32 are possible, particularly having different relative positions of the longitudinal axes of those portions as well as having different sections and dimensions, in one or more directions.

Advantageously according to an embodiment of the disclosure, it is also possible provide for contact probes 21 having non-circular cross section. In a preferred realization example, it is considered for example a contact probe 21 having a rectangular cross section. In that case, also the corresponding guide hole 22A in the guide 22 must have a rectangular cross section and the contact probes 21 inserted therein are always properly placed with respect to the contact pads 26 of the device under test 27.

In the case of rectangular cross section of the contact probes, it is easily verified that the deformation of the contact probe 21 when it contacts the device under test 27 is particularly controlled at the deformed portion 30, the movement occurring in a predefined plane, with the advantage that different probes of this kind, undergoing a vertical movement, keep the same orientation during the deformation.

In a preferred embodiment, the contact probe 21 also has a further deformed section 21A realizing a friction zone with the corresponding guide hole 22A in the guide 22, in order to prevent the probe getting out that guide hole 22A if a device under test 27 is not present.

That embodiment is particularly useful in case of a testing head 20 comprising non-blocked vertical probes, being thus associated to a space transformer, the contact probe 21 in this case being held in the testing head 20 only by the friction with the guide 22 at the guide hole 22A.

By suitably varying the shape of that further deformed section 21A as well as the dimensions of the corresponding guide hole 22A, it is possible to obtain a desired friction value.

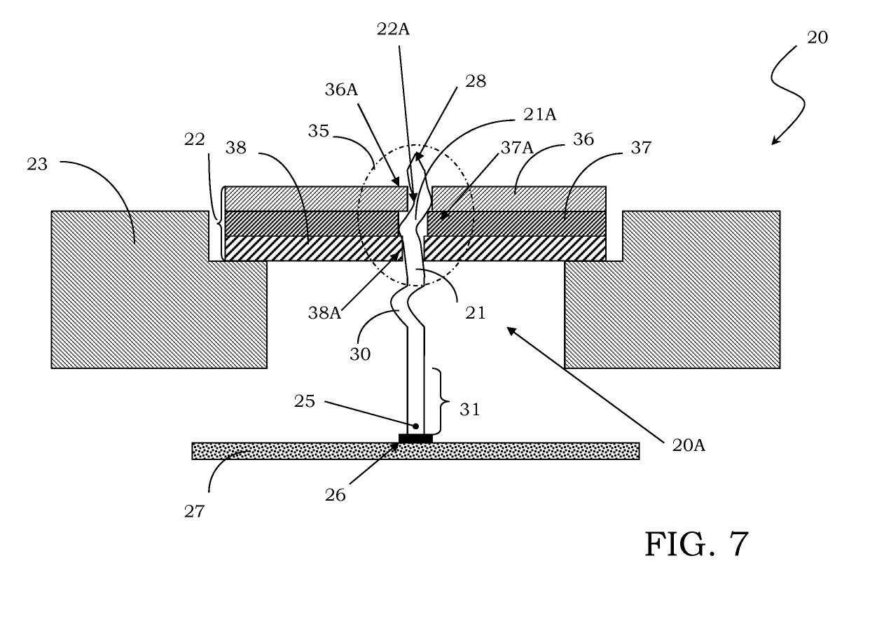

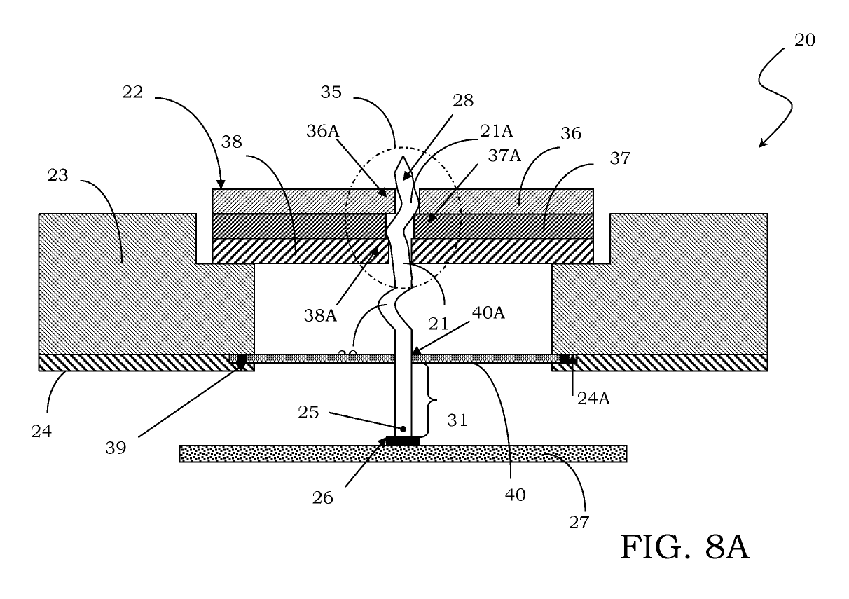

According to an alternative embodiment schematically shown in FIG. 7, the testing head 20 also comprises a plurality of superimposed layers to form the guide 22 for the housing of the contact probes 21.

In particular, as shown in this figure with an exemplificative and non-limiting purpose only, the guide 22 comprises a first layer 36, a second layer 37 and a third layer 38, each provided with respective guide holes 36A, 37A and 38A for the housing of the contact probe 21. It is possible to consider the plurality of guide holes 36A, 37A and 38A as forming the guide hole 22A of the guide 22.

More particularly, the guide holes 36A, 37A and 38A are suitably axially offset with respect to an axis perpendicular to such layers 36, 37 and 38 of the guide 22, the layers being considered as substantially flat and parallel to the device under test 27, such axis thus being the longitudinal axis Y-Y of the contact probe 21. In that way, the guide holes 36A, 37A and 38A cause a deformation of a portion of the contact probe 21, particularly realizing the further deformed section 21A (and thus the friction zone) near the contact head 28.

Substantially, the layers 36, 37 and 38 of the guide 22 are suitably in contact with each other and they can be assembled in order to obtain a guide hole 22A having a non-straight section, having a more or less complicated shape and thus a further deformed section 21A of the contact probe 21, therefore improving the friction grip of the contact probe 21 inside the guide itself. In practice, the layers 36, 37 and 38 are initially superimposed so that the respective guide holes 36A, 37A and 38A are aligned with respect to an axis perpendicular to the layers themselves and then later they are axially offset in order to deform the portion of contact probe 21 enclosed therebetween, realizing the further deformed section 21A.

The combination of the guide holes 36A, 37A and 38A and of the further deformed section 21A of the contact probe 21 realizes suitable sticking means of the contact probe 21, generally shown as 35.

Although in FIG. 7 it is shown a contact probe 21 having an end portion 31 corresponding to the one shown in FIG. 6A, it is clearly possible to use end portions 31 according to the alternative embodiments shown in the FIGS. 6B and 6C.

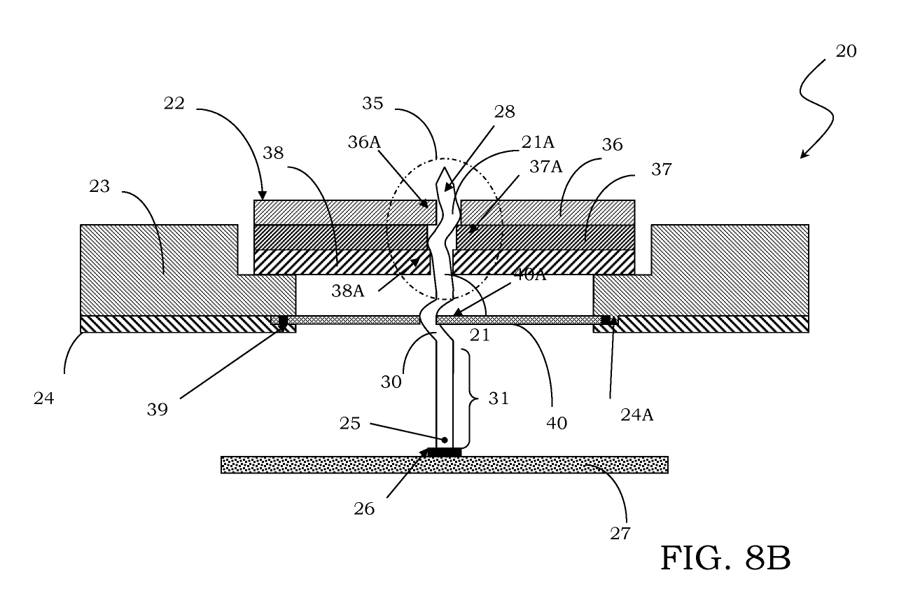

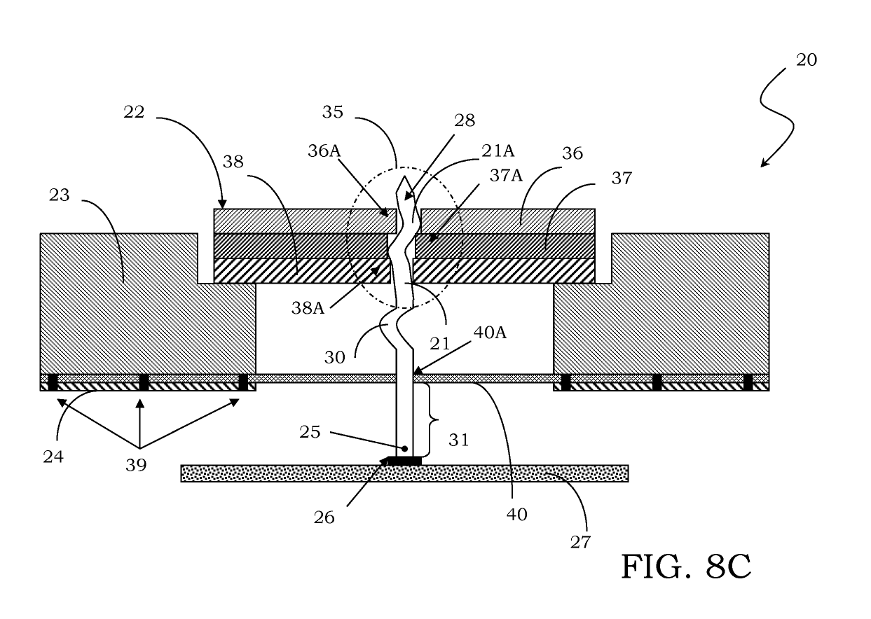

Further, according to a preferred alternative embodiment shown in FIG. 8A, the testing head 20 also comprises one elastic sheet 40, suitably retained within the testing head 20, in particular being associated with the containment element 23.

More particularly, the elastic sheet 40 is retained by a frame 24, particularly a ceramic one, associated with the containment element 23 of the testing head 20 by means of suitable connection means 39. In the realization example shown in FIG. 8A, the elastic sheet 40 is suitably housed in a recess 24A of the ceramic frame 24 and removably fastened thereto by means of connection means 39 in the form of glue dots or screws. In that way, the elastic sheet 40 is disposed near the portion of the contact probe 21 having the end portion 31 and the contact tip 25. It is also possible to consider a configuration where the elastic sheet 40 is suitably housed and removably fastened to the containment element 23.

The elastic sheet 40 is also provided with suitable openings 40A for the passage of the contact probes 21.

Suitably, in the example of FIG. 8A, the contact probes 21 are sized in such a way that the deformed portion 30 is arranged between the guide 22 and the elastic sheet 40 and that the end portion 31 is disposed between the elastic sheet 40 and the device under test 27. Moreover, the end portion 31 is sized so that the contact probe 21 is housed in the corresponding opening 40A of the elastic sheet 40 in a portion of body different from the end portion 31.

Alternatively, as schematically shown in FIG. 8B, the elastic sheet 40 is positioned so that the opening 40A realized therein is positioned in correspondence of the deformed portion 30 of the contact probes 21.

It is also possible to realize an elastic sheet 40 having dimensions similar to the dimensions of the containment element 23, so as to have a portion of the elastic sheet 40 fully contacting the containment element and being fastened thereto, for example by means of screws and by bonding.

As shown in FIG. 8C, in that case it is possible to provide the ceramic frame 24 being associated with the containment element 23, which frame also have dimensions similar to the containment element 23, the elastic sheet 40 thereby having a portion corresponding to the extension of the ceramic frame 24 suitably trapped between that ceramic frame 24 and the containment element 23. Moreover, connection means 39 can be provided in order to fasten the containment element 23, the elastic sheet 40 and the ceramic frame 24 to each other, as right shown in FIG. 8C. In that case too, the elastic sheet 40 can be arranged so that its openings 40A are realized in correspondence of the deformed sections 30 of the contact probes 21 or below those deformed sections 30 (as shown in FIG. 8C).

In particular, the elastic sheet 40 is made of Kapton®.

It should be underlined that, although in the FIGS. 8A-8C the guide 22 has been shown as including a plurality of layers 36, 37 and 38, it is also possible to consider a testing head 20 that includes a single layer guide 22 (of the type shown in FIG. 2) and an elastic sheet 40, positioned below or at the deformed sections 30 of the contact probes 21.

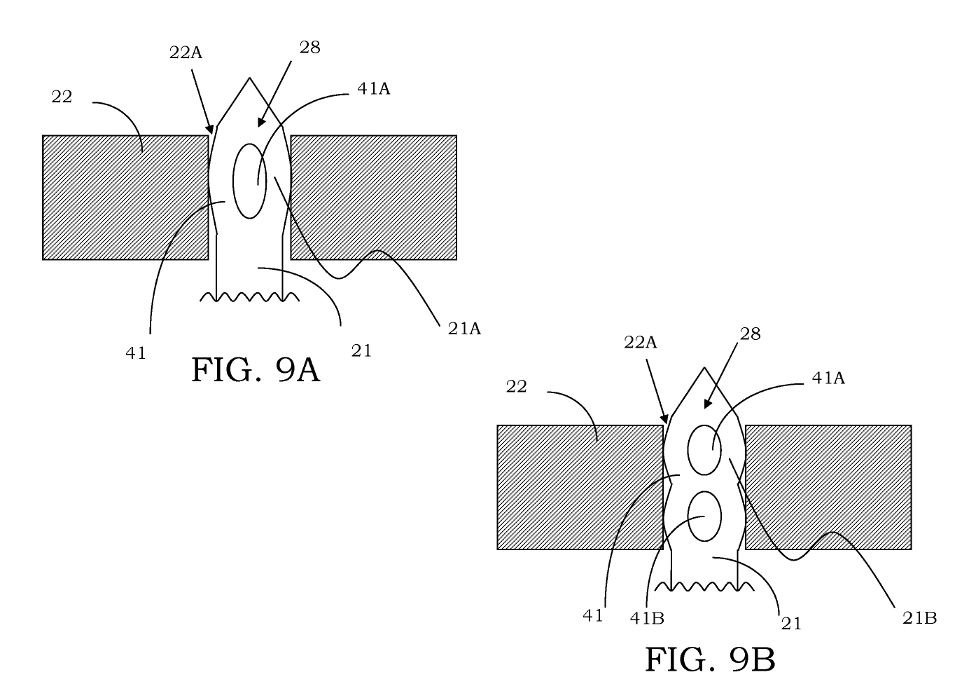

It is also possible to properly stick the contact probes 21 inside the guide holes 22A of the guide 22 by means of a suitable needle configuration of the corresponding portion of the contact probe 21 near the contact head 28, however realizing a further deformed section 21A, as schematically shown in FIGS. 9A and 9B.

More particularly, the further deformed section 21A is configured as a needle eye, equipped with a flexible peripheral portion 41 formed around a suitable hole 41A, as shown in FIG. 9A. That flexible peripheral portion 41 is forcedly inserted in the guide hole 22A of the guide 22, narrowing the hole 41A when sticking the contact probe 21 in the guide hole 22A and when generating the needed friction that guarantees the proper holding of the contact probe 21 itself.

Alternatively, the flexible peripheral portion 41 is formed around at least one first and one second hole 41A and 41B that are both narrowed when sticking the contact probe 21 in the guide hole 22A and that guarantee the needed friction for the holding of the contact probe 21 itself on different contact points distributed along the guide hole 22A, as schematically shown in FIG. 9B.

In conclusion, advantageously according to an embodiment of the disclosure, it is obtained a testing head able to solve the problems left unsolved by the known solutions and having several advantages.

Particularly, as already underlined, the combination of the deformed portion and of the end portion with end portion having a larger length than the known probes allows to control more easily and uniformly the contact of the contact probes on the contact pads of the device under test, preventing an excessive and non-uniform probe consumption, and thus enhancing the working life of the overall head.

Suitably, thanks to the use of “free” deformed sections provided with an end portion “in extension” it is possible, by removing the lower guides used in the known heads, to reduce the length of the contact probe and consequently the one of the containment element and of the overall testing head.

This length reduction of the contact probes allows improving the performances thereof, since it reduces their electrical resistance and thus it increases their current capacity. It is also well known that contact probes having a reduced length have better frequency performances, thanks to the reduced electromagnetic interference with the other probes nearby.

The presence of a thinned deformed portion also allows controlling more precisely the force applied by the contact probe on the device under test. It is also possible to perform a reshape of the contact tips of the contact probes, particularly by using abrasive cloths able to suitably round the end portions, creating suitable contact zones possibly point-shaped or almost point-shaped.

Further, the presence of the deformed portion allows controlling also the horizontal movement (scrub) of the contact tip on the contact pads, simply by suitably varying dimensions or shape of the contact tip, as well as the position of that deformed portion along the contact probe, for example in terms of distance to the contact tip.

In case of rectangular cross section, it is easily verified that the contact probe deformation when contacting the device under test, at the deformed portion, is particularly controlled, the movement occurring in a predefined plane, with the advantage that different probes of this kind, undergoing a vertical movement, keep the same orientation. That control is further improved by the reduction the contact probe cross section right at those deformed portions, which thus are the only ones to be deformed by the pressing contact of the testing head on the device under test.

By using contact probes having a non-circular cross section it is also possible:
to improve the probes orientation during the assembly phase of the testing head, which is guaranteed by the exact correspondence between guide hole and probe;
improve the deformation control during the contact of the probe tip with the pads of the device under test;
to simplify the defective probes replacement, which are also self-centered, once defined the relative position between guide hole and contact pad, thus to simplify the maintenance of the overall testing head.

In the alternative embodiment including the elastic sheet, the same allows guaranteeing an alignment of the contact tips, also following the pressing contact on the device under test. That alignment is particularly important at the edges of the wafer including the integrated circuits to be tested, where the known testing heads have the greatest connection difficulties, due to the non-straight geometry of the edges themselves.

It is also important to underline that the presence of the elastic sheet allows realizing a closure of the testing head itself and thus reduces the problems related to dirt or in any case to external attacks towards the body of the probes, for example as it occurs during the cleaning operations, particularly during the so-called touch-down of the contact tips on the abrasive cloths to remove the residuals from the tips themselves and to possibly thinning them down.

Not the least advantage of using the elastic sheet holding the contact probes is that exactly such elastic sheet is able to avoid the contact among the contact probes bodies, in that way guaranteeing the insulation not only in resting condition but also during the normal working of the testing head and thus during the deformation of the contact probes themselves, which therefore, advantageously according to the present disclosure, do not require expensive covering operations by means of insulating layers.

Finally, it is possible to provide the contact probes with suitable portions being configured as the needle eye, arranged near the contact heads and able to be easily inserted in the guide hole, by making any number of friction points of the contact probe in the guide hole, without a real deformation of the probe itself.

From the foregoing it will be appreciated that, although specific embodiments of the disclosure have been described herein for purposes of illustration, various modifications may be made without deviating from the spirit and scope of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A testing head comprising:
a plurality of contact probes,
at least one guide provided with guide holes for housing the plurality of contact probes, each of the contact probes having at least one contact tip able to ensure mechanical and electrical contact with a corresponding contact pad of a device under test, and
a containment element hosing the guide,
wherein each of the contact probes comprises a deformed portion, placed in a bending zone between the guide and the device under test,
the deformed portion being adapted to further deform during normal working of the testing head and being prolonged, at least towards the device under test, by an end portion having a diameter suitable to realize the contact tip,
the end portion having a longitudinal extension or height exceeding 500 μm.

2. The testing head of claim 1, wherein the deformed portion has a section having at least one dimension lower than a corresponding dimension of the contact probe.

3. The testing head of claim 1, further comprising at least one elastic sheet, retained within the testing head and provided with respective openings for the passage of the contact probes.

4. The testing head of claim 3, wherein the deformed portion of the contact probes is arranged between the guide and the elastic sheet and the end portion is disposed between the elastic sheet and the device under test.

5. The testing head of claim 3, wherein the openings are positioned in correspondence of the deformed portion of the contact probes.

6. The testing head of claim 3, further comprising a frame associated with the containment element and arranged to retain the elastic sheet.

7. The testing head of claim 6, wherein the elastic sheet is connected to the frame by suitable connectors.

8. The testing head of claim 3, wherein the elastic sheet is made of Kapton®.

9. The testing head of claim 1, wherein the deformed portion is substantially C-shaped.

10. The testing head of claim 1, wherein the deformed portion is configured align the contact tip and a contact head of the contact probe according to a longitudinal axis of the contact probe perpendicular to a plane of the device under test.

11. The testing head of claim 1, wherein the deformed portion is configured to axially offset the contact tip and a contact head of the contact probe with respect to a longitudinal axis of the contact probe perpendicular to a plane of the device under test.

12. The testing head of claim 1, wherein the end portion is provided with a thinned portion of suitable diameter to realize the contact tip, the remaining part of the end portion and the contact probe having larger dimensions.

13. The testing head of claim 1, wherein the contact probes have a non-circular cross section and the guide holes have a corresponding non-circular cross section.

14. The testing head of claim 1, wherein each of the contact probes comprises a further deformed section suitable to provide a friction zone with a corresponding guide hole in the guide.

15. The testing head of claim 1, wherein the guide comprises a plurality of superimposed layers, each provided with respective guide holes for the housing of the contact probes.

16. The testing head of claim 15, wherein the guide holes of the layers of the guide are suitably offset with respect to an axis perpendicular to the layers, causing a deformation of a portion of the contact probe and realizing a friction zone.

17. The testing head of claim 1, wherein each of the contact probes comprises at least one configuration shaped as a needle eye, equipped with a flexible peripheral portion formed around a suitable hole which realizes a friction zone between a contact probe and a corresponding guide hole.

18. A testing head comprising vertical probes includes:
a plurality of contact probes,
at least one guide provided with guide holes for housing the plurality of contact probes, each of the contact probes having at least one contact tip able to ensure the mechanical and electrical contact with a corresponding contact pad of a device under test,
a containment element housing the guide, and
at least one elastic sheet, retained within the testing head and provided with respective openings for the passage of the contact probes,
wherein each of the contact probes comprises a deformed portion, placed in a bending zone between the guide and the device under test,
the deformed portion being adapted to further deform during the normal working of the testing head and being prolonged, at least towards the device under test, by an end portion having a diameter suitable to realize the contact tip,
the end portion having a longitudinal extension or height exceeding 500 μm.

19. A testing head comprising vertical probes includes:
a plurality of contact probes,
at least one guide provided with guide holes for housing the plurality of contact probes, each of the contact probes having at least one contact tip able to ensure the mechanical and electrical contact with a corresponding contact pad of a device under test,
a containment element housing the guide,
at least one elastic sheet, retained within the testing head and provided with respective openings for the passage of the contact probes, and
a frame associated with the containment element and arranged to retain the elastic sheet,
wherein each of the contact probes comprises a deformed portion, placed in a bending zone between the guide and the device under test,
the deformed portion being adapted to further deform during the normal working of the testing head and being prolonged, at least towards the device under test, by an end portion having a diameter suitable to realize the contact tip,
the end portion having a longitudinal extension or height exceeding 500 μm.

20. The testing head of claim 19, wherein each of the contact probes comprises a further deformed section suitable to provide a friction zone with a corresponding guide hole in the guide.
